(19) United States
(12) Patent Application Publication
(10) Pub. No.: US 2026/0229449 A1
(43) Pub. Date: Aug. 6, 2026

(54) SAMPLE HOLDER AND METHOD FOR MANUFACTURING SPECIMEN USING THE SAME

(71) Applicant: Samsung Electronics Co., Ltd., Suwon-si (KR)

(72) Inventors: Sungryeol LIM, Suwon-si (KR); Soyeon LEE, Suwon-si (KR); Inhae KIM, Suwon-si (KR); Sanghyun PARK, Suwon-si (KR); Young-Gon SHIN, Suwon-si (KR); Minchul JO, Suwon-si (KR)

(21) Appl. No.: 19/339,965

(22) Filed: Sep. 25, 2025

(30) Foreign Application Priority Data
Feb. 4, 2025 (KR) 10-2025-0013964

(51) Int. Cl. H01J 37/20

(52) U.S. Cl. CPC H01J 37/20

(57) ABSTRACT

A sample holder includes a substrate including a grid-accommodating region and a sample-accommodating region, a first grid coupling portion includes a first support on the grid-accommodating region, the first support protruding in a first direction from the substrate, and a second support on the grid-accommodating region and spaced apart from the first support in a second direction that is perpendicular to the first direction. The second support protrudes in the first direction from the substrate, and a fixing module is on the sample-accommodating region. The fixing module includes an opening that receives a sample of a semiconductor device.

### CROSS-REFERENCE TO RELATED APPLICATION

This application claims priority to Korean Patent Application No. 10-2025-0013964, filed in the Korean Intellectual Property Office on Feb. 4, 2025, the entire contents of which are hereby incorporated by reference.

### BACKGROUND

### Technical Field

Aspects of the present disclosure relate to sample holders and methods for manufacturing specimens using the same.

### DESCRIPTION OF THE RELATED ART

In general, a transmission electron microscope (TEM) is widely utilized as equipment for analyzing the lattice structure and components of a material by transmitting electrons accelerated at high energy through a specimen. Based on these characteristics, the TEM is primarily used for structural analysis for failure analysis and process monitoring of semiconductor devices. In order to perform structural analysis of a semiconductor device, a specimen for TEM analysis must be prepared in advance. A TEM analysis specimen may be manufactured by performing a milling operation on a sample of a semiconductor device using a focused ion beam (FIB).

### SUMMARY

The technical problem to be solved by the present disclosure is to provide a sample holder and a method for manufacturing a specimen using the sample holder, thereby improving working time and productivity.

According to some embodiments of the present disclosure, a sample holder comprising a substrate including a grid-accommodating region and a sample-accommodating region; a first grid coupling portion comprising: a first support on the grid-accommodating region, the first support protruding in a first direction from the substrate; and a second support on the grid-accommodating region and spaced apart from the first support in a second direction that is perpendicular to the first direction, the second support protruding in the first direction from the substrate; and a fixing module on the sample-accommodating region, the fixing module comprising an opening that is configured to receive a sample of a semiconductor device.

According to some embodiments of the present disclosure, a sample holder comprises a substrate including a grid-accommodating region and a sample-accommodating region; a first grid coupling portion comprising a first support on the grid-accommodating region, the first support protruding in a first direction from the substrate; and a second support on the grid-accommodating region and spaced apart from the first support in a second direction that is perpendicular to the first direction, the second support protruding in the first direction from the substrate; a second grid coupling portion including a groove defined within the substrate, the second grid coupling portion being on the grid-accommodating region and spaced apart from the first grid coupling portion in a third direction that is perpendicular to each of the first direction and the second direction; and a fixing module on the sample-accommodating region, the fixing module comprising a third support protruding in the first direction from the substrate, and an elastic assembly spaced apart from the third support in the second direction, the fixing module comprising an opening between the third support and the elastic assembly that is configured to receive a sample of a semiconductor device.

According to some embodiments of the present disclosure, a sample holder comprises a substrate including a grid-accommodating region and a sample-accommodating region; a first grid coupling portion comprising a first support on the grid-accommodating region, the first support protruding in a first direction from the substrate; and a second support on the grid-accommodating region and spaced apart from the first support in a second direction that is perpendicular to the first direction, the second support protruding in the first direction from the substrate; a second grid coupling portion including a groove defined within the substrate, the second grid coupling portion on the grid-accommodating region and spaced apart from the first grid coupling portion in a third direction that is perpendicular to each of the first direction and the second direction; and a fixing module comprising: a third support on the sample-accommodating region, the third support protruding in the first direction from the substrate; and an elastic assembly spaced apart from the third support in the second direction, the fixing module comprising an opening between the third support and the elastic assembly that is configured to receive a sample of a semiconductor device; wherein the first support and the fixing module overlap each other in the second direction.

According to some embodiments of the present disclosure, a method for manufacturing a specimen may include taking out a chip from a wafer, generating a sample by cleaving the chip; arranging the sample so that a section of the sample faces a first direction, and placing the sample on a sample holder, generating a specimen by removing a side surface of a region of interest (ROI) on the section of the sample using a focused ion beam, attaching one end of a probe to the specimen and then separating the specimen from the sample; attaching the specimen to a first grid arranged on the sample holder, using the focused ion beam to partially remove a front surface of the specimen in order to reduce a thickness of the specimen in a second direction intersecting the first direction, and lowering an acceleration voltage of the focused ion beam to remove an amorphous region of the front surface of the specimen.

Further, the sample holder may include a substrate including a grid-accommodating region and a sample-accommodating region, a first grid coupling portion arranged on the grid-accommodating region, the first grid coupling portion including a first support protruding in the first direction from the substrate and a second support arranged on the grid-accommodating region, protruding in the first direction from the substrate, and spaced apart from the first support in the second direction, and a fixing module arranged on the sample-accommodating region. The first grid is arranged on a first grid bar so that a grid finger portion of the first grid faces the first direction, the first grid bar is fixed on the sample holder by the first support and the second support, and the sample is secured on the sample holder by the fixing module.

Further, the sample holder may include a second grid coupling portion including a groove, the second grid coupling portion being arranged on the grid-accommodating region and spaced apart from the first grid coupling portion in a third direction intersecting each of the first direction and the second direction, a fifth support arranged on the groove and protruding in the first direction, and a support cover arranged on the fifth support, a second grid is further arranged on the second grid coupling portion, the second grid is arranged on a second grid bar so that a grid finger portion of the second grid faces the second direction, and the second grid bar is fixed on the sample holder by the fifth support and the support cover.

Further, the sample holder may include a non-magnetic metallic material.

Further, the method may include, before generating the specimen by removing a side surface of the region of interest, forming a protective film on the region of interest.

According to some embodiments of the present disclosure, by reducing the amount of a sample to be removed by ion milling, the time for manufacturing a specimen may be shortened.

According to some embodiments of the present disclosure, the productivity of specimen manufacturing may be enhanced by arranging multiple fixing modules in the sample holder.

According to some embodiments of the present disclosure, because the sample holder may be provided with both a grid-accommodating region and a sample-accommodating region, the process for manufacturing samples may be simplified.

Various and advantageous effects of the present invention are not limited to the above, and may be more readily understood during the course of describing specific embodiments of the present invention.

### BRIEF DESCRIPTION OF THE DRAWINGS

FIG. 1 is a perspective view schematically illustrating a sample holder according to some embodiments of the present disclosure.

FIG. 2 is a cross-sectional view taken along line A-A′ of FIG. 1.

FIG. 3 is a perspective view schematically illustrating a sample holder according to some embodiments of the present disclosure.

FIG. 4 is a cross-sectional view taken along line A-A′ of FIG. 3.

FIGS. 5 through 10 are intermediate step diagrams for describing a specimen-manufacturing method according to some embodiments of the present disclosure.

FIG. 11 is a flowchart illustrating a specimen-manufacturing method according to some embodiments of the present disclosure.

### DETAILED DESCRIPTION

Hereinafter, a sample holder and a specimen-manufacturing method according to some embodiments of the present disclosure are described in detail with reference to the drawings. The embodiments disclosed in the present specification are exemplary embodiments. Therefore, the present invention is not limited thereto and may be implemented in various other forms. Each of the embodiments provided below is not excluded from connection with other embodiments or one or more features of other embodiments that conform to the present invention, whether described herein or not. For example, even if certain aspects described in a particular exemplary embodiment are not described in another exemplary embodiment, unless otherwise mentioned, such aspects may be understood to be associated with the other exemplary embodiment. Moreover, it should be understood that all descriptions of principles, aspects, and exemplary embodiments include structural and functional equivalents thereof. Such equivalents include not only equivalents that are currently well known, but also equivalents that are developed in the future, that is, all devices conceived to perform the same function regardless of structure.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures. It will be understood that when an element is referred to as being “connected” or “coupled” to or “on” another element, it can be directly connected or coupled to or on the other element or intervening elements may be present. In contrast, when an element is referred to as being “directly connected,” “directly attached,” “directly joined,” or “directly coupled” to another element, or as “contacting” or “in contact with” another element (or using any form of the word “contact”), there are no intervening elements present at the point of contact. Furthermore, in the present specification, the same reference numerals may denote the same components.

In the present specification, spatially relative terms such as “over,” “above,” “upper,” “below,” “under,” “beneath,” “lower,” “top,” and “bottom” may be used for convenience in describing the relationship of one component to another component based on the illustrations in the figures. It should be understood that these spatially relative terms include directions other than those depicted in the figures for use or operation of a component in other directions. For example, if a given component in the drawings is turned upside down, a component described as being “below” or “beneath” another component may be oriented “above” that other component, and the “upper” surface of the given component may become its “bottom” or “lower” surface. Accordingly, depending on the situation, the term “below” may include both upward and downward directions, and the term “top” may include both top and bottom. Thus, a component may be oriented in such a manner (rotated by 90 degrees or another angle), and spatially relative descriptions used in the present specification may be interpreted accordingly.

In the present disclosure, although terms such as first, second, and so forth are used to describe various components, the components are not limited by these terms. These terms merely serve to distinguish one component from another. A first component described below may also be a second component within the technical scope of the present disclosure.

Below, a sample holder and a method for manufacturing a specimen using the sample holder according to some embodiments of the present disclosure are described in detail with reference to the drawings.

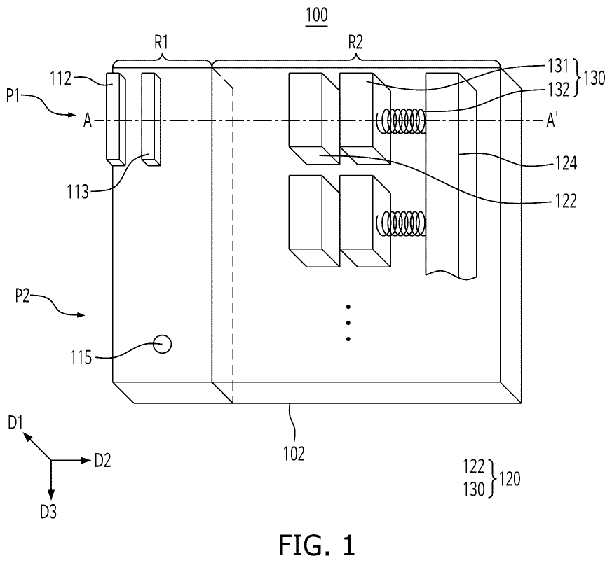

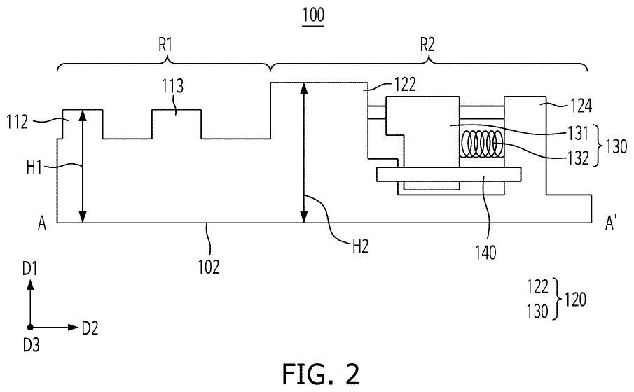

FIG. 1 is a perspective view illustrating a sample holder according to some embodiments of the present disclosure. FIG. 2 is a cross-sectional view taken along line A-A′ of FIG. 1.

Referring to FIGS. 1 and 2, a sample holder 100 may include a substrate 102 that includes a grid-accommodating region R1 and a sample-accommodating region R2. The grid-accommodating region R1 and the sample-accommodating region R2 may be adjacent to each other. The grid-accommodating region R1 may occupy a first portion of the substrate 102 while the sample-accommodating region R2 may occupy a remaining second portion of the substrate 102. The grid-accommodating region R1 and the sample-accommodating region R2 may be integrally formed in the substrate 102. The substrate 102 may be formed of a non-magnetic metallic material. For example, the substrate 102 may be formed of at least one of aluminum, titanium, or molybdenum.

The sample holder 100 may include a first grid coupling portion P1 arranged on the grid-accommodating region R1. The first grid coupling portion P1 may include a first support 112 and a second support 113. The first support 112 may be arranged on the substrate 102. For example, the first support 112 may be arranged on the grid-accommodating region R1. The first support 112 may protrude in a first direction D1 from the substrate 102. As illustrated in FIG. 2, the first direction D1 may refer to a direction perpendicular to an upper surface of the substrate 102. The first support 112 may be integrally formed with the substrate 102. The first support 112 may be formed of a non-magnetic metallic material. For example, the first support 112 may be formed of at least one of aluminum, titanium, or molybdenum. The first support 112 may comprise an upper surface (e.g., relative to the first direction D1) that is at a different level than adjacent surfaces of the substrate 102. For example, the upper surface of the first support 112 may be at a higher level than adjacent surfaces (e.g., on opposing sides of the first support 112) of the substrate 102. In embodiments, the upper surface of the first support 112 may be planar and may be parallel to the second direction D2 and the third direction D3.

The second support 113 may have a shape that is similar to the first support 112. The second support 113 may be arranged on the substrate 102. For example, the second support 113 may be arranged on the grid-accommodating region R1. The second support 113 may protrude in the first direction D1 from the substrate 102. The second support 113 may comprise an upper surface (e.g., relative to the first direction D1) that is at a different level than adjacent surfaces of the substrate 102. For example, the upper surface of the second support 113 may be at a higher level than adjacent surfaces (e.g., on opposing sides of the second support 113) of the substrate 102. In embodiments, the upper surface of the second support 113 may be planar and may be parallel to the second direction D2 and the third direction D3. In embodiments, the upper surface of the second support 113 may be co-planar with the upper surface of the first support 112. In other embodiments, the upper surface of the second support 113 may be parallel to, but not co-planar with, the upper surface of the first support 112. The second support 113 may be spaced apart from the first support 112 in a second direction D2. As illustrated in FIG. 2, the second direction D2 may refer to a direction intersecting, and perpendicular to, the first direction D1. For example, the second direction D2 may refer to a direction parallel to the upper surface of the substrate 102. Accordingly, the substrate 102 may be exposed between the first support 112 and the second support 113. In embodiments, the portion of the substrate 102 that is exposed between the first support 112 and the second support 113 is at a lower level than a level of the upper surfaces of the first support 112 and the second support 113, such that the portion of the substrate 102 that is exposed between the first support 112 and the second support 113 may be recessed from the first support 112 and the second support 113. The second support 113 may be integrally formed with the substrate 102. The second support 113 may be formed of a non-magnetic metallic material. For example, the second support 113 may be formed of at least one of aluminum, titanium, or molybdenum.

The first support 112 and the second support 113 may extend in a third direction D3. Here, the third direction D3 may refer to a direction that intersects, and is perpendicular to, each of the first direction D1 and the second direction D2. The first support 112 and the second support 113 may extend in the third direction D3 to form a rectangular parallelepiped shape. For example, as illustrated in FIG. 1, the first support 112 and the second support 113 may each have a length extending lengthwise along the third direction D3 that is greater than a width extending widthwise along the second direction D2. The first support 112 and the second support 113 may comprise the same shape with the same dimensions (e.g., as illustrated in FIG. 1), or may comprise different shapes. However, the first support 112 and the second support 113 are not limited thereto and may be formed in any shape. As described below, a grid bar may be arranged between the first support 112 and the second support 113. A grid may be arranged on the grid bar.

The sample holder 100 may include a second grid coupling portion P2 arranged on the grid-accommodating region R1. The second grid coupling portion P2 may be spaced apart in the third direction D3 from the first grid coupling portion P1. The second grid coupling portion P2 may be formed separately from the first grid coupling portion P1. In some embodiments, the second grid coupling portion P2 may occupy a partial region of the substrate 102 on the grid-accommodating region R1. The second grid coupling portion P2 may comprise a different structure and construction than the first grid coupling portion P1, for example, with the second grid coupling portion P2 not comprising a first support or a second support. Instead, the second grid coupling portion P2 may include a groove 115 (e.g., a hollow channel or hole that extends at least partially into the substrate 102). The groove 115 may be formed at any position on the second grid coupling portion P2. The groove 115 may pass through a portion of the substrate 102 in the first direction D1. The groove 115 may have any shape, such as circular or polygonal. As described below, a grid bar may be arranged on the second grid coupling portion P2. A grid may be arranged on the grid bar.

The sample holder 100 may include a fixing module 120 arranged on the sample-accommodating region R2. The fixing module 120 may be spaced apart from the grid-accommodating region R1 in the second direction D2. The fixing module 120 may be arranged on the substrate 102. A plurality of fixing modules 120 may be arranged on the sample-accommodating region R2. For example, multiple fixing modules 120 may be spaced apart from each other in the third direction D3. The fixing module 120 may overlap the first support 112 in the second direction D2. In addition, the fixing module 120 may overlap the second support 113 in the second direction D2. For example, an axis extending in the second direction D2 may intersect the first support 112, the second support 113, and the fixing module 120.

As described below, a sample may be arranged in the fixing module 120. Furthermore, the sample may be secured by the fixing module 120, such that the sample is held in place and limited from moving. For example, the fixing module 120 may define an opening that is configured to receive the sample S.

The fixing module 120 may include a third support 122 and an elastic assembly 130 that are spaced apart from each other to form an opening within which a sample S may be received. The third support 122 may protrude in the first direction D1 from the substrate 102. The third support 122 may be integrally formed with the substrate 102. The third support 122 may also extend in the third direction D3. The third support 122 may be formed of a non-magnetic metallic material. For example, the third support 122 may be formed of at least one of aluminum, titanium, or molybdenum. In embodiments, the third support 122 may be positioned adjacent to the grid-accommodating region R1, with the second support 113 positioned between the first support 112 and the third support 122. The third support 122 may represent the portion of the fixing module 120 that is in closest proximity to the grid-accommodating region R1.

In some embodiments, a height H1 of the first support 112 in the first direction D1 may be lower than a height H2 of the third support 122 in the first direction D1. For example, the height H2 of the third support 122 in the first direction D1 may be higher than the height H1 of the first support 112 in the first direction D1. In embodiments, the second support 113 may comprise a second height that is less than the height H2 of the third support 122. As illustrated in FIG. 2, the second height of the second support 113 may be the same as the height H1 of the first support 112, or the second height of the second support 113 may be different from the height H1 of the first support 112. The heights (e.g., H1, H2, second height) may be measured from a bottom, or lowermost surface, of the substrate 102 to an uppermost surface of the respective support (e.g., height H1 measured to uppermost surface of the first support 112, etc.).

The elastic assembly 130 may include a base portion 131 and an elastic portion 132. The base portion 131 may be arranged on the substrate 102. The base portion 131 may protrude in the first direction D1 from the substrate 102. The base portion 131 may be spaced apart from the substrate 102 in the first direction D1 and arranged on the substrate 102. At least one surface of the base portion 131 and at least one surface of the third support 122 may contact each other based on the elastic motion of the elastic portion 132. The base portion 131 may be formed of a non-magnetic metallic material. For example, the base portion 131 may be formed of at least one of aluminum, titanium, or molybdenum. The base portion 131 may be located on an opposite side of the third support 122 from the second support 113, such that the third support 122 may be between the second support 113 and the base portion 131. The base portion 131 and the third support 122 may be spaced apart from each other to define the opening within which the sample S may be received.

The elastic portion 132 may be arranged on the base portion 131. For example, the elastic portion 132 may be arranged on one side surface of the base portion 131 facing the second direction D2, for example, with the base portion 131 positioned between the third support 122 and the elastic portion 132. The elastic portion 132 may extend in the second direction D2. In some embodiments, the elastic portion 132 may be a compression coil spring. The elastic portion 132 may undergo elastic movement along the second direction D2. For example, the elastic portion 132 may comprise an elastically deformable material that may be deformed (e.g., compressed or extended) in response to a deforming force, and the elastic portion 132 may return to its original shape when the deforming force is removed. The elastic portion 132 may apply a force in the second direction D2 toward the base portion 131, with the elastic portion 132 applying a biasing force to the base portion 131 to bias the base portion 131 toward the third support 122. The elastic portion 132 may be formed of a non-magnetic metallic material. For example, the elastic portion 132 may be formed of at least one of non-magnetic stainless steel, aluminum, titanium, or molybdenum.

In some embodiments, the sample holder 100 may further include a fourth support 124 arranged on the sample-accommodating region R2. The fourth support 124 may be arranged on the substrate 102. The fourth support 124 may protrude in the first direction D1 from the substrate 102. The fourth support 124 may be spaced apart from the elastic assembly 130 in the second direction D2, for example, with the fourth support 124 spaced apart from the base portion 131. Furthermore, the fourth support 124 may be spaced apart from the third support 122 in the second direction D2. The fourth support 124 may be integrally formed with the substrate 102. The fourth support 124 may extend in the third direction D3. The fourth support 124 may be formed of a non-magnetic metallic material. For example, the fourth support 124 may be formed of at least one of aluminum, titanium, or molybdenum. Here, the base portion 131 may be arranged between the third support 122 and the elastic portion 132. The elastic portion 132 may be arranged between the base portion 131 and the fourth support 124. For example, opposing ends of the elastic portion 132 may be coupled to the base portion 131 and the fourth support 124, respectively, with a first end of the elastic portion 132 coupled to the base portion 131, and an opposing second end of the elastic portion 132 coupled to the fourth support 124. As described below, a sample may be arranged between the third support 122 and the base portion 131. Here, the gap between the third support 122 and the base portion 131 may be adjusted by the elastic movement of the elastic portion 132. When the gap between the third support 122 and the base portion 131 becomes smaller, the sample may be gripped between the third support 122 and the base portion 131. The fourth support 124 may be fixed and non-movable relative to the substrate 102, such that the fourth support 124 may not move in response to a force applied by the elastic portion 132. Rather, the base portion 131 may be movable relative to the substrate 102 and the fourth support 124, such that the elastic portion 132 can apply a force to the base portion 131 to cause the base portion 131 to move.

In some embodiments, the sample holder 100 may include a guide portion 140. The guide portion 140 may be arranged on the sample-accommodating region R2. The guide portion 140 may extend in the second direction D2. The guide portion 140 may connect the third support 122 and the fourth support 124. For example, one end of the guide portion 140 may be coupled to the third support 122, and an opposing end of the guide portion 140 may be coupled to the fourth support 124, thereby connecting the third support 122 and the fourth support 124. The guide portion 140 may function to guide the movement of the base portion 131 relative to the third support 122. For example, the guide portion 140 may extend through the base portion 131, or the base portion 131 may be movably attached to the guide portion 140. As such, the base portion 131 can move in the second direction D2 relative to the guide portion 140. The base portion 131 may be guided by the guide portion 140, which reduces the likelihood of unintended movement of the base portion 131 in the first direction D1 and/or the third direction D3. The guide portion 140 may extend along an axis that is parallel to the second direction D2. The position of the guide portion 140 in FIG. 2 is merely exemplary, and the guide portion 140 may be located at other locations while still functioning as described, and in some embodiments, a plurality of guide portions 140 may be provided. The elastic assembly 130 may be arranged between the plurality of guide portions 140.

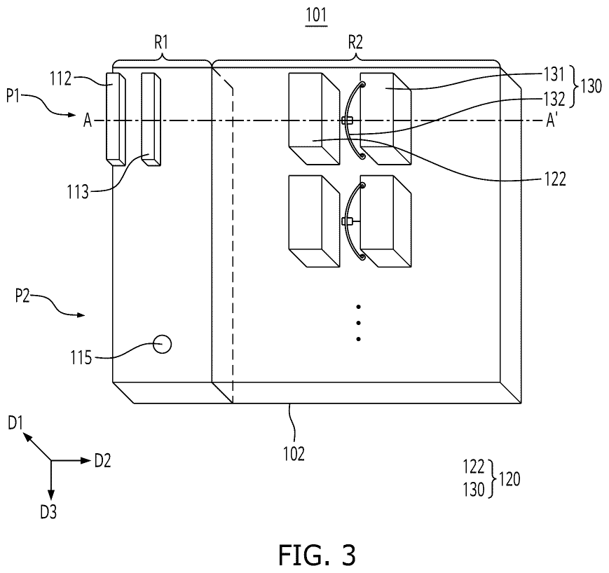

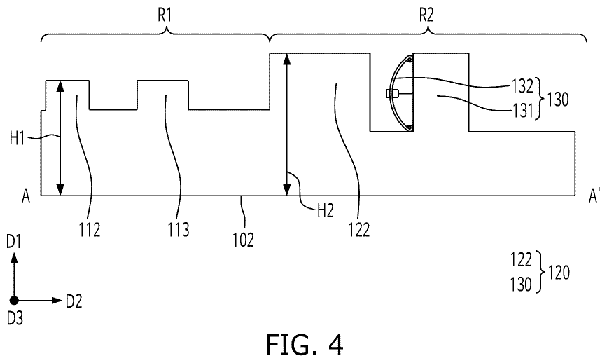

FIG. 3 is a perspective view illustrating a sample holder according to some embodiments of the present disclosure. FIG. 4 is a cross-sectional view taken along line A-A′ of FIG. 3.

Referring to FIGS. 3 and 4, a sample holder 101 may include the substrate 102 that includes the grid-accommodating region R1 and the sample-accommodating region R2. The substrate 102, the grid-accommodating region R1 and the sample-accommodating region R2 may be identical to the substrate 102, the grid-accommodating region R1 and the sample-accommodating region R2 described relative to FIGS. 1-2. The grid-accommodating region R1 and the sample-accommodating region R2 may be adjacent to each other. The grid-accommodating region R1 and the sample-accommodating region R2 may be integrally formed in the substrate 102. The substrate 102 may include a non-magnetic metallic material. For example, the substrate 102 may include at least one of aluminum, titanium, or molybdenum.

The sample holder 101 may include the first grid coupling portion P1 arranged on the grid-accommodating region R1. The first grid coupling portion P1 may include the first support 112 and the second support 113 that may be identical to the first support 112 and the second support 113 described above. The first support 112 may be arranged on the substrate 102. For example, the first support 112 may be arranged on the grid-accommodating region R1. The first support 112 may protrude in the first direction D1 from the substrate 102. Here, the first direction D1 may refer to a direction perpendicular to an upper surface of the substrate 102. The first support 112 may be integrally formed with the substrate 102. The first support 112 may be formed of a non-magnetic metallic material. For example, the first support 112 may be formed of at least one of aluminum, titanium, or molybdenum.

The second support 113 may have a shape that is similar to the first support 112. The second support 113 may be arranged on the substrate 102. For example, the second support 113 may be arranged on the grid-accommodating region R1. The second support 113 may protrude in the first direction D1 from the substrate 102. The second support 113 may be spaced apart from the first support 112 in a second direction D2. Here, the second direction D2 may refer to a direction intersecting, and perpendicular to, the first direction D1. For example, the second direction D2 may refer to a direction parallel to the upper surface of the substrate 102. Accordingly, the substrate 102 may be exposed between the first support 112 and the second support 113. The second support 113 may be integrally formed with the substrate 102. The second support 113 may be formed of a non-magnetic metallic material. For example, the second support 113 may be formed of at least one of aluminum, titanium, or molybdenum.

The first support 112 and the second support 113 may extend in the third direction D3. Here, the third direction D3 may refer to a direction that intersects, and is perpendicular to, each of the first direction D1 and the second direction D2. The first support 112 and the second support 113 may extend in the third direction D3 to form a rectangular parallelepiped shape. However, the first support 112 and the second support 113 are not limited thereto and may be formed in any shape. As described below, a grid bar may be arranged between the first support 112 and the second support 113. A grid may be arranged on the grid bar.

The sample holder 101 may include the second grid coupling portion P2 (e.g., identical to the second grid coupling portion P2 described above) arranged on the grid-accommodating region R1. The second grid coupling portion P2 may be spaced apart in the third direction D3 from the first grid coupling portion P1. The second grid coupling portion P2 may be formed independently from the first grid coupling portion P1. In some embodiments, the second grid coupling portion P2 may represent a partial region of the substrate 102 on the grid-accommodating region R1. The second grid coupling portion P2 may include the groove 115, which may be identical to the groove 115 described above. The groove 115 may be formed at any position on the second grid coupling portion P2. The groove 115 may pass through a portion of the substrate 102 in the first direction D1. The groove 115 may have any shape, such as circular or polygonal. As described below, a grid bar may be arranged on the second grid coupling portion P2. A grid may be arranged on the grid bar.

The sample holder 101 may include the fixing module 120 (e.g., which may be identical to the fixing module 120 described above) arranged on the sample-accommodating region R2. The fixing module 120 may be spaced apart from the grid-accommodating region R1 in the second direction D2. The fixing module 120 may be arranged on the substrate 102. A plurality of fixing modules 120 may be arranged on the sample-accommodating region R2. For example, multiple fixing modules 120 may be spaced apart from each other in the third direction D3. As described below, a sample may be arranged in the fixing module 120. Furthermore, the sample may be secured by the fixing module 120.

The fixing module 120 may include the third support 122 and the elastic assembly 130, wherein the third support 122 and the elastic assembly 130 may be identical to the third support 122 and the elastic assembly 130 described above). The third support 122 may protrude in the first direction D1 from the substrate 102. The third support 122 may be integrally formed with the substrate 102. The third support 122 may be formed of a non-magnetic metallic material. For example, the third support 122 may be formed of at least one of aluminum, titanium, or molybdenum.

In some embodiments, the height H1 of the first support 112 in the first direction D1 may be lower than the height H2 of the third support 122 in the first direction D1. For example, the height H2 of the third support 122 in the first direction D1 may be higher than the height H1 of the first support 112 in the first direction D1.

The elastic assembly 130 may include the base portion 131 and an elastic portion 132. The base portion 131 may be arranged on the substrate 102. The base portion 131 may protrude in the first direction D1 from the substrate 102. The base portion 131 may be spaced apart from the substrate 102 in the first direction D1 and arranged on the substrate 102. The base portion 131 may be formed of a non-magnetic metallic material. For example, the base portion 131 may be formed of at least one of aluminum, titanium, or molybdenum.

The elastic portion 132 may be arranged on the base portion 131. For example, the elastic portion 132 may be arranged on one side surface of the base portion 131 facing the second direction D2. The elastic portion 132 may extend in the third direction D3. In some embodiments, the elastic portion 132 may be a leaf spring. A leaf spring may comprise one or more thin, flexible strips of elastic material (e.g., metal) that may be stacked to form a curved or rounded shape. Opposing ends of the leaf spring may be attached to the base portion 131, while a center of the leaf spring may extend outwardly from the base portion 131 and may project toward the third support 122. In this case, the elastic portion 132 may be arranged between the third support 122 and the base portion 131. For example, the elastic portion 132 may be coupled to the base portion 131. The elastic portion 132 may undergo elastic movement along the second direction D2, for example, with the center of the leaf spring (e.g., the elastic portion 132) extending toward the third support 122 and away from the base portion 131. The center of the leaf spring may define a gap or recess between the center of the leaf spring and the third support 122, and a sample may be positioned in this gap or recess. The elastic portion 132 may be formed of a non-magnetic metallic material. For example, the elastic portion 132 may be formed of at least one of non-magnetic stainless steel, aluminum, titanium, or molybdenum.

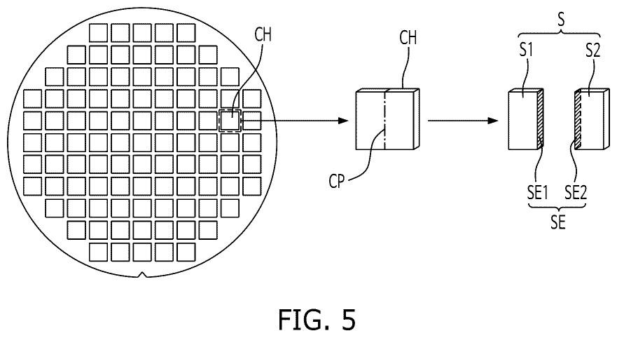

FIGS. 5 through 10 are intermediate step diagrams for describing a specimen-manufacturing method according to some embodiments of the present disclosure. For convenience, detailed descriptions regarding components identical or similar to those described in the embodiments set forth with reference to FIGS. 1 through 4 may be omitted.

Referring to FIG. 5, according to some embodiments of the method for manufacturing a semiconductor device of the present disclosure, a chip CH may be taken out from a wafer WF. The wafer WF may include at least one chip CH. The wafer WF may be formed of a semiconductor material such as single-crystal or polycrystalline silicon. The chip CH may include any semiconductor device. The semiconductor device may include active elements and/or passive elements. The active element may be a semiconductor chip in the form of an integrated circuit (IC) in which hundreds to millions or more elements are integrated into a single chip. The semiconductor device may be, for example, a logic chip or a memory chip. A logic chip may be a central processor (CPU) or a graphics processor (GPU). For example, a logic chip may be an application processor (AP) chip including at least one of a CPU, GPU, digital signal processor, cryptographic processor, microprocessor, or microcontroller, or may be an analog-to-digital converter, an ASIC (application-specific integrated circuit), etc., or may be a chipset including a certain combination of the above. A memory chip may be a stacked memory such as HBM. The memory chip may include a volatile memory (for example, DRAM), a non-volatile memory (for example, ROM), or flash memory.

A cutting process may be performed to take out the chip CH from the wafer WF. For example, the chip CH may be taken out from the wafer WF by dicing or laser cutting.

Subsequently, a sample S may be generated by cleaving the chip CH. The sample S may be a portion of the semiconductor device. For example, a first sample S1 and a second sample S2 may be generated by cleaving along a crystal plane CP of the chip CH. Here, a newly formed surface by the cleaving of the chip CH may be referred to as a section SE of the sample S. For example, the first sample S1 may have a first section SE1 formed by cleaving, and the second sample S2 may have a second section SE2 formed by cleaving. Unlike the illustrated embodiment, multiple samples S may be generated. As illustrated in FIG. 5, the first section SE1 may be the portion of the first sample S1 that faces the second sample S2 during cleaving, with the first section SE1 lying within the crystal plane CP prior to cleaving. The second section SE2 may be the portion of the second sample S2 that faces the first sample S1 during cleaving, with the second section SE2 lying within the crystal plane CP prior to cleaving.

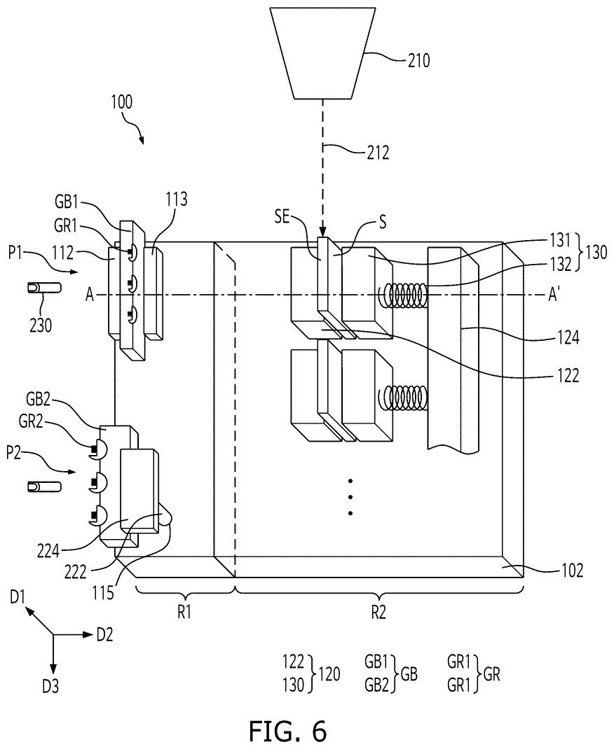

Referring to FIGS. 6 through 9, the sample S may be arranged on the sample holder 100 so that the section SE of the sample S faces the first direction D1. In some embodiments, the sample S may be secured on the sample holder 100 by the fixing module 120. If multiple samples S are generated, each sample S among the multiple samples S may be secured on the sample holder 100 by each fixing module 120 among multiple fixing modules 120 arranged on the sample holder 100. Specifically, based on the elastic movement of the elastic portion 132, the gap between the base portion 131 and the third support 122 may be adjusted. For example, the sample S may be positioned between the base portion 131 and the third support 122, and the elastic portion 132 may apply a biasing force to the base portion 131. This biasing force may cause the base portion 131 to move toward the third support 122, such that the sample S may be compressed between, and held in place by, the base portion 131 and the third support 122. Accordingly, the sample S arranged between the base portion 131 and the third support 122 may be secured. Therefore, the sample S may be easily attached and detached. In some embodiments, the sample holder 100 may be formed of a non-magnetic metallic material.

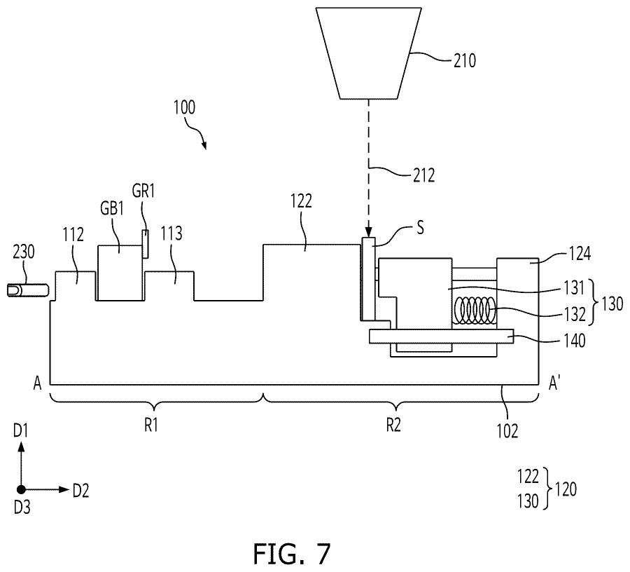

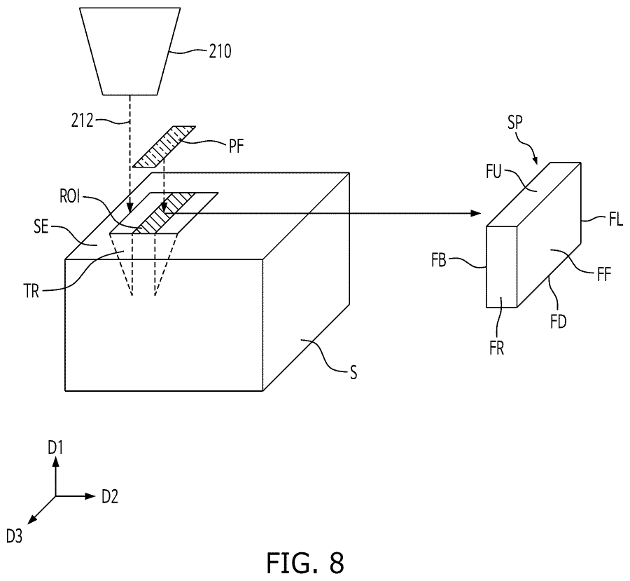

In some embodiments, a focused ion beam column 210 may be configured to be placed over the sample S. For purposes of illustration and to avoid visual obstruction of portions of the sample holder 100, FIG. 6 illustrates the focused ion beam column 210 at an angle relative to the sample S. However, in operation, and as illustrated in FIGS. 7-8, the focused ion beam column 210 may be spaced apart from the sample S along the first direction D1, for example, with an axis that is parallel to the first direction D1 extending through the focused ion beam column 210 and the sample S. Here, the focused ion beam column 210 may be a component of a device for carrying out the specimen-manufacturing method according to some embodiments of the present disclosure. For example, the device for performing the specimen-manufacturing method may be a dual FIB (Focused Ion Beam) system. A focused ion beam 212, which may comprise gallium ions, may be emitted from the focused ion beam column 210. As such, the focused ion beam column 210 may generate and direct the focused ion beam 212 toward the sample S, which cuts and thins a portion of the sample, allowing the portion of the sample to be inspected via transmission electron microscopy (TEM).

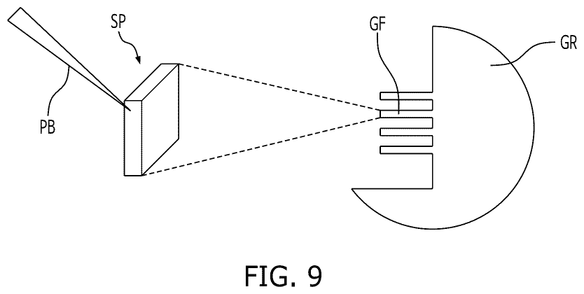

In some embodiments, a grid bar GB may be arranged on the sample holder 100. At least one grid GR may be arranged on the grid bar GB. The grid bar GB may be an elongated structure that may be planar, and the grid bar GB may be attached to one of the grid coupling portions P1, P2. The grid GR may include multiple grid finger portions GF. The grid GR may be attached to the grid bar GB, and the grid GR may comprise one or more projections (e.g., extensions, protuberances, etc.) that may extend outwardly from the grid bar GB and may form the multiple grid finger portions GF. For example, a first grid bar GB1 may be arranged on the grid-accommodating region R1 of the sample holder 100. Specifically, the first grid bar GB1 may be arranged on the first grid coupling portion P1. The first grid bar GB1 may be coupled or fixed onto the sample holder 100 by the first support 112 and the second support 113, for example, with the first grid bar GB1 positioned between, and held in place by, the first support 112 and the second support 113. The first grid bar GB1 may be fixed by a fixing member 230. For example, the fixing member 230 may pass through the first support 112 in the second direction D2 and fix the first grid bar GB1 in a fixed position relative to the first support 112 and the second support 113. The fixing member 230 may be a screw or other mechanical fastener that may pass through an opening in the first support 112 and/or the second support 113. The fixing member 230 may engage the first grid bar GB1, for example, by passing through the first grid bar GB1, by applying a compressive force to the first grid bar GB1, etc. such that the fixing member 230 may fix the first grid bar GB1 in the fixed position. A first grid GR1 may be arranged on the first grid bar GB1. Here, the first grid GR1 may be arranged on the first grid bar GB1 so that the grid finger portion GF of the first grid GR1 faces the first direction D1. The grid finger portion GF (e.g., also illustrated in FIG. 9) may comprise a plurality of the projections that may be spaced apart to define channels between adjacent projections, such that the sample, or a portion of the sample, may be positioned in a channel and held in place by the grid finger portion GF.

In some embodiments, the sample holder 100 may further include a fifth support 222 and a support cover 224. The fifth support 222 may be arranged on the second grid coupling portion P2. The fifth support 222 may be arranged in the groove 115, for example, with the fifth support 222 received within the groove 115. The fifth support 222 may have a shape corresponding to the shape of the groove 115. However, the present disclosure is not limited thereto. The fifth support 222 may be formed of a non-magnetic metallic material. For example, the fifth support 222 may be formed of at least one of aluminum, titanium, or molybdenum.

The support cover 224 may be arranged on the fifth support 222. The support cover 224 may be formed of a non-magnetic metallic material. For example, the support cover 224 may be formed of at least one of aluminum, titanium, or molybdenum. The support cover 224 may be attached to the fifth support 222, for example, to an end of the fifth support 222. The support cover 224 may be in a fixed position relative to the fifth support 222 and the substrate 102.

A second grid bar GB2 may be further arranged on the grid-accommodating region R1 of the sample holder 100. Specifically, the second grid bar GB2 may be arranged on the second grid coupling portion P2. The second grid bar GB2 may be coupled or fixed onto the sample holder 100 by the fifth support 222 and the support cover 224. For example, the second grid bar GB2 may be attached to the fifth support 222, such that the second grid bar GB2 may be in a fixed position relative to the fifth support 222. The second grid bar GB2 may be structurally identical to the first grid bar GB1. The second grid bar GB2 may be fixed by the fixing member 230. The fixing member 230 may extend through an opening in the second grid bar GB2 and/or the fifth support 222 to fix and attach the second grid bar GB2 to the fifth support 222. A second grid GR2 may be arranged on the second grid bar GB2. Here, the second grid GR2 may be arranged on the second grid bar GB2 so that the grid finger portion GF of the second grid GR2 faces the second direction D2. The second grid GR2 may be structurally identical to the first grid GR1, and may comprise the one or more projections (e.g., extensions, protuberances, etc.) that may extend outwardly from the second grid bar GB2 and may form the multiple grid finger portions GF. Referring to FIG. 8, FIG. 8 illustrates an orientation of the sample S relative to the first direction D1, the second direction D2, and the third direction D3 when the sample S is held by the sample holder 100 (e.g., as illustrated in FIG. 7). For example, FIG. 8 illustrates the orientation of the sample S while the sample S is held by the sample holder 100 between the third support 122 and the base portion 131. For purposes of illustration, portions of the sample holder 100 are omitted from view in FIG. 8 so as to not obstruct the sample S. In some embodiments, the sample S may include a region of interest (ROI). The region of interest ROI may refer to an area of the section SE of the sample S that is desired to be observed and/or analyzed. For example, the region of interest ROI may be identified by using a scanning electron microscope (SEM). After placing the sample S on the sample holder 100, the side surface of the region of interest ROI on the section SE of the sample S may be removed using the focused ion beam 212, such that a specimen SP may be generated. The specimen SP is a portion of the sample S that contains the region of interest ROI, wherein the specimen SP may be removed from the sample S by the focused ion beam 212. The direction in which the focused ion beam 212 is emitted may be perpendicular to the section SE of the sample S, for example, as illustrated in FIGS. 7-8. For example, the focused ion beam 212 may be emitted in a straight line along the first direction D1.

In some embodiments, the specimen SP may have an upper surface FU, a lower surface FD, a front surface FF, a back surface FB, a left surface FL, and a right surface FR. The upper surface FU may be a surface whose normal vector faces the first direction D1 and that corresponds to the region of interest ROI. For example, when the upper surface FU comprises a flat or planar shape, an axis (e.g., normal vector) that is perpendicular to the upper surface FU may extend parallel to the first direction D1. The lower surface FD may be a surface facing an opposite direction from the upper surface FU, with the lower surface FD located on an opposite side from the upper surface FU. The front surface FF may be a surface connected to the upper surface FU and having a normal vector extending in the second direction D2. The back surface FB may be a surface parallel to, and opposite from, the front surface FF. The right surface FR may be a surface connected to the upper surface FU and having a normal vector extending in the third direction D3. The left surface FL may be a surface parallel to, and opposite from, the right surface FR.

In some embodiments, both side surfaces facing the second direction D2 of the region of interest ROI may be removed. In this case, by removing the sample S along the first direction D1 using the focused ion beam 212, the specimen SP may be formed. Accordingly, trenches TR may be formed on both sides of the region of interest ROI in the second direction D2, for example, with the trenches TR formed due to the focused ion beam 212 impinging upon the sample S.

In some embodiments, the focused ion beam 212 may be used to form the front surface FF and the back surface FB of the specimen SP. Specifically, by forming a trench TR that penetrates in a straight line along the long edge of the upper surface FU of the specimen SP using the focused ion beam 212, the front surface FF and the back surface FB of the specimen SP may be formed. Subsequently, by removing an additional portion of the sample S using the focused ion beam 212, the specimen SP may be completely separated from the sample S.

In some embodiments, before the step of removing the side surface of the region of interest ROI to form the specimen SP, a protective film PF may be formed on, or applied to, the region of interest ROI. For example, the protective film PF may be made of one material selected from carbon (C), platinum (Pt), tungsten (W), or silica (SiO2). The protective film PF may be formed of a material that may protect the region of interest ROI from damage that may be caused by the focused ion beam 212 during formation of the specimen SP. For example, the protective film PF may be applied to the region of interest ROI prior to directing the focused ion beam 212 toward the sample S. After the protective film PF is applied to the region of interest ROI, the side surface of the protective film PF may be removed using the focused ion beam 212, and the specimen SP may be generated. For example, both side surfaces in the second direction D2 of the protective film PF may be removed. For example, an area of the protective film PF may be larger than that of the region of interest ROI. In this case, portions of the protective film PF may be also removed by the focused ion beam 212.

According to some embodiments of the present disclosure, multiple samples S may be placed on the sample holder 100, and thus multiple specimens SP may be manufactured. In addition, the multiple specimens SP may be easily transferred to multiple grids GR. Therefore, the productivity of specimen SP manufacturing may be enhanced.

As illustrated in FIG. 9, after manufacturing the specimen SP, one end of a probe PB may be attached to the specimen SP, and the specimen SP may then be separated from the sample S. To separate the specimen SP from the sample S, an additional portion of the sample S may be removed using the focused ion beam 212. The probe PB may be used to separate the specimen SP from the sample S, and move the specimen SP to the grid GR. The separated specimen SP may be attached to a grid GR arranged on the sample holder 100. For example, the specimen SP may be attached to a first grid GR1. Specifically, the specimen SP may be attached to a grid finger portion GF of the first grid GR1. In embodiments, the specimen SP may be positioned within one of the channels between adjacent grid fingers of the grid finger portion GF.

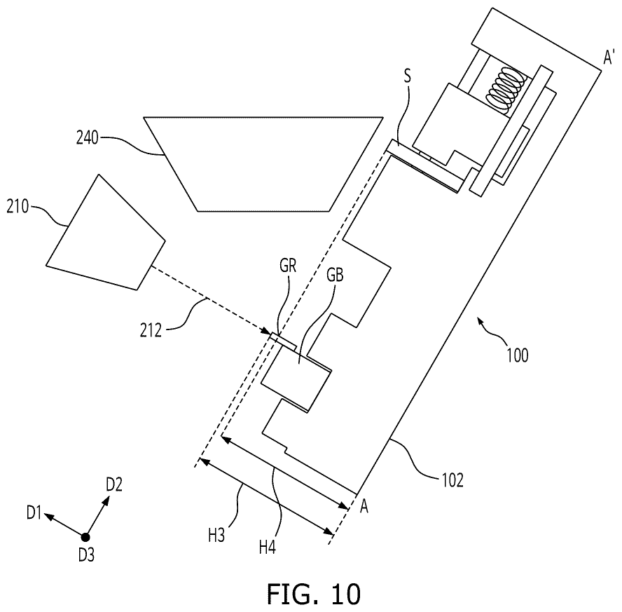

Next, as illustrated in FIG. 10, to reduce the thickness of the specimen SP in the second direction D2, a portion of the front surface FF and/or the back surface FB of the specimen SP may be removed using the focused ion beam 212. The focused ion beam 212 may be directed toward the front surface FF and/or the back surface FB of the specimen SP to remove portions of the front surface FF and/or the back surface FB, thus reducing a thickness of the specimen SP. Finally, by lowering the acceleration voltage of the focused ion beam 212 and removing the amorphous region on the front surface FF and/or the back surface FB of the specimen SP, a specimen SP for TEM observation and/or analysis may be obtained.

Referring to FIG. 10, in some embodiments, a height H3 from the topmost portion of the grid GR to the bottom of the substrate 102 may be higher than a height H4 from the topmost portion of the sample S (e.g., from which the specimen SP has been removed) to the bottom of the substrate 102. Accordingly, when tilting the sample holder 100 to align the focused ion beam column 210 with the grid GR in a straight line, a collision or interference between the scanning electron microscope column 240 and the sample S may be prevented.

According to some embodiments of the present disclosure, the amount of the sample S that needs to be removed by ion milling to form the specimen SP may be greatly reduced. Therefore, by shortening the manufacturing time for the specimen SP for observation and/or analysis, the productivity of the TEM observation and/or analysis process may be improved.

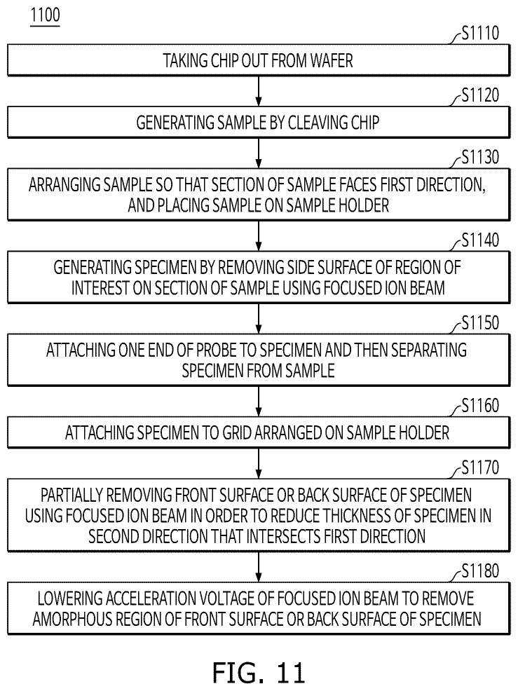

FIG. 11 is a flowchart 1100 illustrating a specimen-manufacturing method according to some embodiments of the present disclosure. For convenience, detailed descriptions regarding components identical or similar to those described in detail in the embodiments set forth with reference to FIGS. 1 through 10 may be omitted.

Referring to FIG. 11, the specimen-manufacturing method may include a step S1110 of taking a chip out from a wafer. Referring to FIG. 5, the wafer WF may include at least one chip CH. The wafer WF may be formed of single-crystal or polycrystalline silicon. The chip CH may include any semiconductor device. A cutting process may be performed to take out the chip CH from the wafer WF. For example, the chip CH may be taken out from the wafer WF by dicing or laser cutting.

Next, the specimen-manufacturing method may include a step S1120 of generating a sample by cleaving the chip. Referring to FIG. 5, the sample S may be generated by cleaving along a crystal plane CP of the chip CH. Multiple samples S may be generated as the chip CH is cleaved. Here, a newly formed surface by cleaving of the chip CH may be referred to as a section SE of the sample S.

Next, the specimen-manufacturing method may include a step S1130 of arranging the sample so that the section of the sample faces the first direction, and placing the sample on a sample holder. Referring to FIG. 6, the sample S may be arranged on the sample holder 100 so that the section SE of the sample S faces the first direction D1. Here, the first direction D1 may refer to a direction perpendicular to an upper surface of the substrate 102 of the sample holder 100. In some embodiments, the sample S may be secured on the sample holder 100 by the fixing module 120. If multiple samples S are generated, each sample S among the multiple samples S may be secured on the sample holder 100 by each fixing module 120 among multiple fixing modules 120 arranged on the sample holder 100. Specifically, the gap between the base portion 131 and the third support 122 may be adjusted by the elastic movement of the elastic portion 132. Accordingly, the sample S arranged between the base portion 131 and the third support 122 may be secured.

Next, the specimen-manufacturing method may include a step S1140 of generating a specimen by removing a side surface of a region of interest on the section of the sample using a focused ion beam. Referring to FIG. 8, the region of interest ROI may be identified on the section SE of the sample S. After placing the focused ion beam column 210 on the side surface of the region of interest ROI, a portion of the sample S may be removed by scanning the focused ion beam 212 along the first direction D1. As a portion of the sample S is removed, a specimen SP including the region of interest ROI may be generated.

Next, the specimen-manufacturing method may include a step S1150 of attaching one end of a probe to the specimen and then separating the specimen from the sample, and a step S1160 of attaching the specimen to a grid arranged on the sample holder. Referring to FIGS. 6 and 9, one end of the probe PB is attached to the specimen SP generated from the sample S, and the specimen SP may be separated from the sample S. The specimen SP may then be attached to a grid GR. The grid GR may include a first grid GR1 or a second grid GR2 arranged on the grid-accommodating region R1. For example, the specimen SP separated from the sample S may be moved and attached to the first grid GR1 via the probe PB.

Next, the specimen-manufacturing method may include a step S1170 of partially removing a front surface and/or a back surface of the specimen using a focused ion beam in order to reduce a thickness of the specimen in the second direction D2 that intersects the first direction. Referring to FIGS. 6 through 9, after attaching the specimen SP to the grid GR, a portion of the front surface FF or the back surface FB of the specimen SP may be removed to reduce the thickness of the specimen SP in the second direction D2. For example, after attaching the specimen SP to the first grid GR1, a portion of the front surface FF of the specimen SP and/or a portion of the back surface FB of the specimen SP may be removed. Finally, the specimen-manufacturing method may include a step S1180 of lowering an acceleration voltage of the focused ion beam to remove an amorphous region of the front surface or the back surface of the specimen.

While the present invention has been described above with reference to certain embodiments and figures, the present invention is not limited thereto, and various modifications and changes may be made by those of ordinary skill in the art within the technical spirit of the present invention and the equivalent scope of the claims described below.

What is claimed is:

1. A sample holder comprising:
a substrate including a grid-accommodating region and a sample-accommodating region;
a first grid coupling portion comprising:
a first support on the grid-accommodating region, the first support protruding in a first direction from the substrate; and
a second support on the grid-accommodating region and spaced apart from the first support in a second direction that is perpendicular to the first direction, the second support protruding in the first direction from the substrate; and
a fixing module on the sample-accommodating region, the fixing module comprising an opening that is configured to receive a sample of a semiconductor device.

2. The sample holder according to claim 1,
wherein the fixing module comprises:
a third support protruding in the first direction from the substrate; and
an elastic assembly spaced apart from the third support in the second direction, wherein the opening is formed between the third support and the elastic assembly.

3. The sample holder according to claim 2, wherein a height of the third support in the first direction is higher than a height of the first support in the first direction.

4. The sample holder according to claim 2,
wherein the elastic assembly comprises:
a base portion on the substrate, the base portion spaced apart from the third support in the second direction such that the opening is formed between the base portion and the third support; and
an elastic portion attached to the base portion, the elastic portion formed from an elastically deformable material and configured to apply a biasing force toward the third support.

5. The sample holder according to claim 4, wherein the elastic portion is between the third support and the base portion.

6. The sample holder according to claim 4, wherein the base portion is spaced apart from the substrate in the first direction.

7. The sample holder according to claim 4, wherein the elastic portion is formed from a non-magnetic metallic material.

8. The sample holder according to claim 4, further comprising:
a fourth support spaced apart in the second direction from the elastic assembly, the fourth support extending in a third direction intersecting each of the first direction and the second direction,
wherein the elastic portion is between the base portion and the fourth support, the elastic portion configured to apply the biasing force to the base portion to move the base portion toward the third support.

9. The sample holder according to claim 8, further comprising:
a guide portion extending in the second direction and configured to connect the third support and the fourth support, the base portion configured to move relative to the guide portion.

10. The sample holder according to claim 1, further comprising:
a second grid coupling portion including a groove defined within the substrate, the second grid coupling portion on the grid-accommodating region and spaced apart from the first grid coupling portion in a third direction that is perpendicular to each of the first direction and the second direction.

11. The sample holder according to claim 10, further comprising:
a fifth support received within the groove and protruding in the first direction; and
a support cover attached to the fifth support and spaced apart from the substrate.

12. The sample holder according to claim 1, wherein the first support and the fixing module overlap each other in the second direction.

13. A sample holder comprising:
a substrate including a grid-accommodating region and a sample-accommodating region;
a first grid coupling portion comprising:
a first support on the grid-accommodating region, the first support protruding in a first direction from the substrate; and
a second support on the grid-accommodating region and spaced apart from the first support in a second direction that is perpendicular to the first direction, the second support protruding in the first direction from the substrate;
a second grid coupling portion including a groove defined within the substrate, the second grid coupling portion being on the grid-accommodating region and spaced apart from the first grid coupling portion in a third direction that is perpendicular to each of the first direction and the second direction; and
a fixing module on the sample-accommodating region, the fixing module comprising a third support protruding in the first direction from the substrate, and an elastic assembly spaced apart from the third support in the second direction, the fixing module comprising an opening between the third support and the elastic assembly that is configured to receive a sample of a semiconductor device.

14. The sample holder according to claim 13,
wherein the elastic assembly comprises:
a base portion on the substrate the base portion spaced apart from the third support in the second direction such that the opening is formed between the base portion and the third support; and
an elastic portion attached to the base portion, the elastic portion formed from an elastically deformable material and configured to apply a biasing force toward the third support.

15. The sample holder according to claim 14, wherein the base portion is spaced apart from the substrate in the first direction.

16. The sample holder according to claim 14, wherein the elastic portion is formed from a non-magnetic metallic material.

17. The sample holder according to claim 14, further comprising:
a fourth support spaced apart in the second direction from the elastic assembly, the fourth support extending in the third direction,
wherein the elastic portion is between the base portion and the fourth support, the elastic portion configured to apply the biasing force to the base portion to move the base portion toward the third support.

18. The sample holder according to claim 17, further comprising:
a guide portion extending in the second direction and connecting the third support and the fourth support, the base portion configured to move relative to the guide portion.

19. The sample holder according to claim 13, wherein the first support and the fixing module overlap each other in the second direction.

20. A sample holder comprising:
a substrate including a grid-accommodating region and a sample-accommodating region;
a first grid coupling portion comprising:
a first support on the grid-accommodating region, the first support protruding in a first direction from the substrate; and
a second support on the grid-accommodating region and spaced apart from the first support in a second direction that is perpendicular to the first direction, the second support protruding in the first direction from the substrate;
a second grid coupling portion including a groove defined within the substrate, the second grid coupling portion on the grid-accommodating region and spaced apart from the first grid coupling portion in a third direction that is perpendicular to each of the first direction and the second direction; and
a fixing module comprising:
a third support on the sample-accommodating region, the third support protruding in the first direction from the substrate; and
an elastic assembly spaced apart from the third support in the second direction, the fixing module comprising an opening between the third support and the elastic assembly that is configured to receive a sample of a semiconductor device;
wherein the first support and the fixing module overlap each other in the second direction.
